(19) United States
(12) Patent Application Publication
(10) Pub. No.: US 2023/0144249 A1
(43) Pub. Date: May 11, 2023

(54) RADIO WAVE ABSORBER

(71) Applicant: NITTO DENKO CORPORATION, Ibaraki-shi, Osaka (JP)

(72) Inventors: Hirokazu Tanaka, Osaka (JP); Yosuke Nakanishi, Osaka (JP); Hironobu Machinaga, Osaka (JP)

(73) Assignee: NITTO DENKO CORPORATION, Ibaraki-shi, Osaka (JP)

(21) Appl. No.: 17/915,243

(22) PCT Filed: Mar. 5, 2021
(86) PCT No.: PCT/JP2021/008821

§ 371 Date: Sep. 28, 2022

(30) Foreign Application Priority Data
Mar. 30, 2020 (JP) 2020-061582

(51) Int. Cl. H05K 9/00

(52) U.S. Cl. CPC H05K 9/0088; H05K 9/009; H05K 9/0075

(57) ABSTRACT

A radio wave absorber includes a resistive layer, an electroconductive layer, and a dielectric layer. The resistive layer has a first main surface with a plurality of first openings formed at equal intervals. The electroconductive layer has a second main surface with a plurality of second openings formed at equal intervals. The dielectric layer is disposed between the resistive layer and the electroconductive layer. In the radio wave absorber, a value obtained by dividing a larger value out of a first ratio and a second ratio by a smaller value out of the first ratio and the second ratio is 1.3 or more. The first ratio is a ratio (G_{R}/W_{R}) of a size G_{R} of the first opening to a distance W_{R} between the first openings. The second ratio is a ratio (G_{C}/W_{C}) of a size G_{C} of the second opening to a distance W_{C} between the second openings.

### TECHNICAL FIELD

The present invention relates to a radio wave absorber.

### BACKGROUND ART

Hitherto, there have been attempts to provide transparent radio wave absorbers.

For example, Patent Literature 1 describes an electromagnetic wave absorber having transparency. In the electromagnetic wave absorber, a reflective layer composed of a thin-line mesh pattern is formed on one surface of a transparent substrate. A transparent solid dielectric layer lies along the reflective layer with an adhesive agent layer interposed therebetween. Furthermore, a frequency selective shielding layer lies along the solid dielectric layer with an adhesive agent layer interposed therebetween.

The frequency selective shielding layer is composed of a thin-line pattern of an FSS element formed on one surface of a transparent substrate. A transparent solid dielectric layer lies along the frequency selective shielding layer with an adhesive agent layer interposed therebetween. A frequency selective shielding layer lies along the solid dielectric layer with an adhesive agent layer interposed therebetween. The frequency selective shielding layer is composed of a thin-line pattern of an FSS element formed on one surface of a transparent substrate. The thin-line mesh pattern of the reflective layer and the thin-line pattern of each frequency selective shielding layer have a line width of 15 to 80 μm.

Patent Literature 2 describes a radio wave absorber having a dielectric, and a radio wave absorbing surface having a phase adjustment function is formed on a surface of the dielectric. In addition, a radio wave reflecting surface is formed on a surface of the dielectric opposite to the radio wave absorbing surface. A plurality of independent metal wire elements are provided on the radio wave absorbing surface. In addition, a plurality of independent metal wire elements are provided on the radio wave reflecting surface. Therefore, by using a material having a high light transmittance as the dielectric, the light transmittance of the radio wave absorber is increased, and for example, the radio wave absorber can be attached to window glass.

### CITATION LIST

### Patent Literature

Patent Literature 1: JP 2009-170887 A
Patent Literature 2: JP 2003-78276 A

### SUMMARY OF INVENTION

### Technical Problem

In the electromagnetic wave absorber described in Patent Literature 1, a plurality of thin-line mesh patterns overlap each other. In addition, in the electromagnetic wave absorber described in Patent Literature 2, the plurality of independent metal wire elements on the radio wave absorbing surface and the plurality of independent metal wire elements on the radio wave reflecting surface overlap each other. It is known that, when geometrically regularly distributed patterns are caused to overlap each other, mottles called moiré are caused due to the magnitudes of the intervals of the patterns. Moiré may diminish the appearance of an electromagnetic wave absorber. In Patent Literatures 1 and 2, no specific countermeasures against moiré have been considered, and the technologies described in Patent Literatures 1 and 2 have room for reconsideration from the viewpoint of taking countermeasures against moiré.

In view of such circumstances, the present invention provides a radio wave absorber in which it is less likely to visually recognize moiré caused due to overlap of a plurality of layers having openings.

### Solution to Problem

The present invention provides a radio wave absorber including:

a resistive layer having a first main surface and having a plurality of first openings formed at equal intervals in a first direction along the first main surface;

an electroconductive layer having a second main surface and having a plurality of second openings formed at equal intervals in a second direction along the second main surface; and

a dielectric layer disposed between the resistive layer and the electroconductive layer in a thickness direction of the resistive layer, wherein

a value obtained by dividing a larger value out of a first ratio and a second ratio by a smaller value out of the first ratio and the second ratio is 1.3 or more, the first ratio being a ratio of a size of the first opening in the first direction to a distance between the nearest first openings, and the second ratio being a ratio of a size of the second opening in the second direction to a distance between the nearest second openings.

### Advantageous Effects of Invention

In the above radio wave absorber, it is less likely to visually recognize moiré caused due to overlap of the resistive layer and the electroconductive layer.

### BRIEF DESCRIPTION OF THE DRAWINGS

FIG. 1A is a plan view of one main surface of an example of a radio wave absorber according to the present invention.

FIG. 1B is a plan view of another main surface of the radio wave absorber shown in FIG. 1A.

FIG. 2A is a cross-sectional view of the radio wave absorber taken along a line IIa-IIa shown in FIG. 1A.

FIG. 2B is a plan view showing a modification of the radio wave absorber shown in FIG. 1A.

FIG. 2C is a plan view showing another modification of the radio wave absorber shown in FIG. 1A.

FIG. 3A is a plan view showing another example of the radio wave absorber according to the present invention.

FIG. 3B is a plan view showing still another example of the radio wave absorber according to the present invention.

FIG. 3C is a plan view showing still another example of the radio wave absorber according to the present invention.

FIG. 4 is a cross-sectional view showing still another example of the radio wave absorber according to the present invention.

### DESCRIPTION OF EMBODIMENTS

As for a radio wave absorber, a configuration of including a resistive layer, an electroconductive layer, and a dielectric layer disposed between the resistive layer and the electroconductive layer has been known. In such a radio wave absorber, if the resistive layer and the electroconductive layer each have a plurality of openings, this is advantageous in terms of imparting transparency to the radio wave absorber. In addition, in order to suppress spatial variations in the transparency of the radio wave absorber and the radio wave absorption performance of the radio wave absorber, it is advantageous to form the plurality of openings at equal intervals in each of the resistive layer and the electroconductive layer. Meanwhile, in this case, moiré can be caused due to overlap of the resistive layer and the electroconductive layer. Therefore, the present inventors have thoroughly studied countermeasures against moiré. As a result, the present inventors have newly found that, when the plurality of openings are formed in each of the resistive layer and the electroconductive layer such that a predetermined condition is satisfied, it is less likely to visually recognize moiré in the radio wave absorber. On the basis of this new finding, the present inventors have conceived of a radio wave absorber according to the present invention. As used herein, “transparency” means transparency to visible light, unless otherwise described.

Embodiments of the present invention will be described with reference to the drawings. The present invention is not limited to the following embodiments.

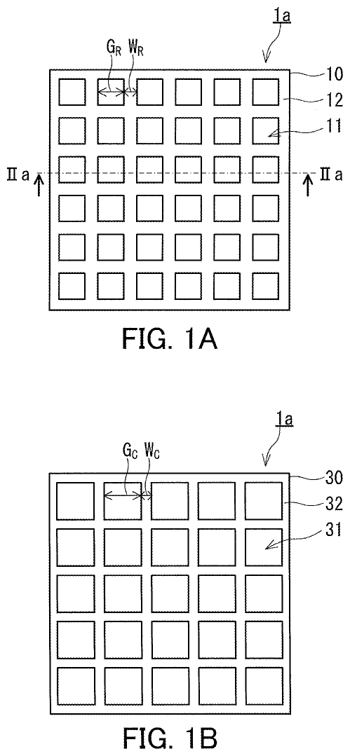

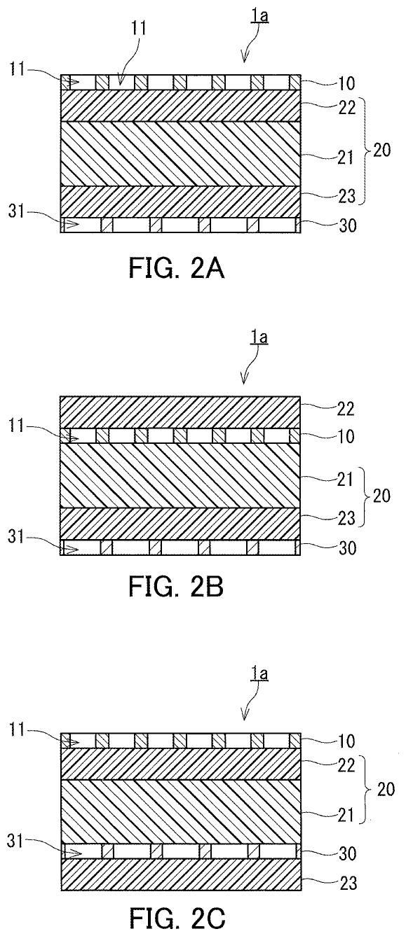

As shown in FIG. 1A, FIG. 1B, and FIG. 2A, a radio wave absorber 1a includes a resistive layer 10, an electroconductive layer 30, and a dielectric layer 20. The resistive layer 10 has a first main surface 12, and has a plurality of first openings 11 formed at equal intervals in a first direction along the first main surface 12. The electroconductive layer 30 has a second main surface 32, and has a plurality of second openings 31 formed at equal intervals in a second direction along the second main surface 32. The dielectric layer 20 is disposed between the resistive layer 10 and the electroconductive layer 30 in the thickness direction of the resistive layer 10. In the radio wave absorber 1a, a value D obtained by dividing a larger value out of a first ratio Ra and a second ratio Rb by a smaller value out of the first ratio Ra and the second ratio Rb is 1.3 or more. The first ratio Ra is the ratio (G_{R}/W_{R}) of a size G_{R} of the first opening 11 in the first direction to a distance W_{R} between the nearest first openings 11. The second ratio Rb is the ratio (G_{C}/W_{C}) of a size G_{C} of the second opening 31 in the second direction to a distance W_{C} between the nearest second openings 31.

In the radio wave absorber 1a, the resistive layer 10 having the plurality of first openings 11 and the electroconductive layer 30 having the plurality of second openings 31 overlap each other. The plurality of first openings 11 are formed at equal intervals in the first direction, and the plurality of second openings 31 are formed at equal intervals in the second direction. Therefore, it is considered that moiré occurs in the radio wave absorber 1a. However, in the radio wave absorber 1a, since the above value D is 1.3 or more, it is less likely to visually recognize moiré. The reason for this is not clear, but it is considered that, when the value D is 1.3 or more, moiré occurs at a narrow pitch that makes it difficult to recognize the moiré with the naked eye.

The upper limit of the value D is not limited to a specific value. The upper limit of the value D can be adjusted, for example, such that the radio wave absorber 1a has desired radio wave absorption performance.

The magnitude relationship between the first ratio Ra and the second ratio Rb is not limited to a specific relationship as long as the value D is 1.3 or more in the radio wave absorber 1a. The first ratio Ra may be higher than the second ratio Rb, or may be lower than the second ratio Rb.

The first ratio Ra is not limited to a specific value as long as the value D is 1.3 or more in the radio wave absorber 1a. The first ratio Ra is, for example, 5 or more. Accordingly, G_{R} is less likely to be small with respect to the distance W_{R}, so that it is less likely to visually recognize a frame that is in contact with the first openings 11. The first ratio Ra may be 10 or more, or may be 20 or more. The first ratio Ra is, for example, 100 or less. Accordingly, the sheet resistance of the resistive layer 10 is easily adjusted in a desired range. The first ratio Ra may be 70 or less, or may be 50 or less.

The second ratio Rb is not limited to a specific value as long as the value D is 1.3 or more in the radio wave absorber 1a. The second ratio Rb is, for example, 5 or more. Accordingly, G_{C} is less likely to be small with respect to the distance W_{C}, so that it is less likely to visually recognize a frame that is in contact with the second openings 31. The second ratio Rb may be 10 or more, or may be 20 or more. The second ratio Rb is, for example, 100 or less. Accordingly, the sheet resistance of the electroconductive layer 30 is easily adjusted in a desired range. The second ratio Rb may be 70 or less, or may be 50 or less.

The distance W_{R} between the nearest first openings 11 is not limited to a specific value as long as the value D is 1.3 or more in the radio wave absorber 1a. The distance W_{R} is, for example, 100 μm or less, and may be 50 μm or less. On the other hand, the distance W_{R} is desirably 10 μm or less. Accordingly, it is less likely to visually recognize the frame that is in contact with the first openings 11, when the resistive layer 10 is viewed in a plan view. In addition, the opening ratio of the resistive layer 10 is easily increased, so that the resistive layer 10 easily has high transparency. The distance W_{R} is, for example, 5 μm or more.

The size G_{R} of each first opening 11 in the first direction is not limited to a specific value as long as the value D is 1.3 or more in the radio wave absorber 1a. The size G_{R} is, for example, 50 μm or more, and may be 100 μm or more, or may be 400 μm or more. The size G_{R} is, for example, 1000 μm or less, and may be 700 μm or less, or may be 500 μm or less.

The thickness of the resistive layer 10 is not limited to a specific value. The thickness of the resistive layer 10 is, for example, 10 nm or more, and may be 15 nm or more, or may be 20 nm or more. The thickness of the resistive layer 10 is, for example, 500 nm or less. Accordingly, the resistive layer 10 is less likely to warp, so that cracks are less likely to occur in the resistive layer 10. The thickness of the resistive layer 10 may be 450 nm or less, or may be 400 nm or less.

The sheet resistance of the resistive layer 10 is not limited to a specific value. The sheet resistance of the resistive layer 10 is, for example, 350 to 600Ω/□, and may be 100 to 700Ω/□. The sheet resistance of the resistive layer 10 can be measured, for example, according to the eddy current method.

A specific resistance ρ1 of the material forming the resistive layer 10 is not limited to a specific value. The specific resistance of the material forming the resistive layer 10 is, for example, 4×10⁻⁵ to 1×10⁻⁴ Ω·cm. The specific resistance of the material forming the resistive layer 10 may be 5×10⁻⁵ to 1×10⁻⁴ Ω·cm.

The specific resistance ρ1 can be determined on the basis of a relationship of Rf=(ρ1/t1){(G_{R}+W_{R})/W_{R}}, for example, by taking a fragment having a predetermined dimension from the resistive layer 10 and measuring a sheet resistance Rf of the fragment, the size G_{R} of the first opening 11, the distance W_{R} between the nearest first openings 11, and a thickness t1 of the resistive layer 10. The sheet resistance Rf can be measured according to the eddy current method using a non-contact resistance meter. The size G_{R} and the distance W_{R} can be determined by observing the fragment using an optical microscope. In addition, the thickness t1 of the resistive layer 10 can be determined, for example, by observing a cross-section of the resistive layer 10 using a transmission electron microscope (TEM). Moreover, the specific resistance ρ1 of the material forming the resistive layer 10 may be determined by analyzing the material composition of the material, forming a film having the same composition as the material composition, and measuring the sheet resistance and the thickness of the film.

The material forming the resistive layer 10 is not limited to a specific material. The material forming the resistive layer 10 may be an inorganic material such as metals, alloys, and metal oxides, or may be an organic material such as electroconductive polymers and carbon nanotubes.

The resistive layer 10 may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

The opening ratio of the resistive layer 10 is not limited to a specific value as long as the value D is 1.3 or more in the radio wave absorber 1a. The resistive layer 10 has, for example, an opening ratio of 65% or more. Accordingly, the resistive layer 10 easily has high transparency. The opening ratio of the resistive layer 10 is a ratio Saf/(Saf+Sbf) of an opening area Saf of the plurality of first openings 11 to a sum Saf+Sbf of the opening area Saf of the plurality of first openings 11 and an area Sbf of the non-opening portion of the resistive layer 10 when the resistive layer 10 is viewed in a plan view.

The opening ratio of the resistive layer 10 is desirably 70% or more and more desirably 75% or more. The opening ratio of the resistive layer 10 is, for example, 99% or less, and may be 98% or less, or may be 97% or less.

The arrangement of the plurality of first openings 11 is not limited to a specific arrangement as long as the value D is 1.3 or more in the radio wave absorber 1a. For example, the first direction may include a plurality of alignment directions intersecting each other. For example, in the resistive layer 10, the plurality of first openings 11 are arranged such that the centers thereof form a square lattice on the first main surface 12. In other words, in the resistive layer 10, the first direction includes alignment directions orthogonal to each other.

The shape of each first opening 11 is not limited to a specific shape as long as the value D is 1.3 or more in the radio wave absorber 1a. For example, each first opening 11 has a square shape in a plan view.

The distance W_{C} between the nearest second openings 31 is not limited to a specific value as long as the value D is 1.3 or more in the radio wave absorber 1a. The distance W_{C} is, for example, 100 μm or less, and may be 50 μm or less. On the other hand, the distance W_{C} is desirably 10 μm or less. Accordingly, it is less likely to visually recognize the frame that is in contact with the second openings 31, when the electroconductive layer 30 is viewed in a plan view. In addition, the opening ratio of the electroconductive layer 30 is easily increased, so that the electroconductive layer 30 easily has high transparency. The distance W_{R} is, for example, 5 μm or more.

The size G_{C} of each second opening 31 in the second direction is not limited to a specific value as long as the value D is 1.3 or more in the radio wave absorber 1a. The size G_{C} is, for example, 50 μm or more, and may be 100 μm or more, or may be 400 μm or more. The size G_{C} is, for example, 1000 μm or less, and may be 700 μm or less, or may be 500 μm or less.

The thickness of the electroconductive layer 30 is not limited to a specific value. The thickness of the electroconductive layer 30 is, for example, 50 nm or more, and may be 100 nm or more, or may be 500 nm or more. The thickness of the electroconductive layer 30 is, for example, 2000 nm or less. Accordingly, the electroconductive layer 30 is less likely to warp, so that cracks are less likely to occur in the electroconductive layer 30. The thickness of the electroconductive layer 30 may be 1000 nm or less, or may be 500 nm or less.

The sheet resistance of the electroconductive layer 30 is not limited to a specific value. The sheet resistance of the electroconductive layer 30 is typically lower than the sheet resistance of the resistive layer 10. The sheet resistance of the electroconductive layer 30 is, for example, 100Ω/□ or less, and may be 50Ω/□ or less, or may be 30Ω/□ or less. The sheet resistance of the electroconductive layer 30 is, for example, 0.1Ω/□ or more, may be 0.5Ω/□ or more, or may be 1Ω/□ or more. The sheet resistance of the electroconductive layer 30 can be measured, for example, according to the eddy current method.

A specific resistance ρ2 of the material forming the electroconductive layer 30 is not limited to a specific value. The specific resistance of the material forming the electroconductive layer 30 is, for example, 2×10⁻⁵ Ω·cm or less. The specific resistance of the material forming the electroconductive layer 30 may be 1×10⁻⁵ Ω·cm or less. The specific resistance of the material forming the electroconductive layer 30 is, for example, 1×10⁻⁶ Ω·cm or more. The specific resistance ρ2 can be determined, for example, in the same manner as the specific resistance ρ1.

The material forming the electroconductive layer 30 is not limited to a specific material. The material forming the electroconductive layer 30 may be an inorganic material such as metals, alloys, and metal oxides, or may be an organic material such as electroconductive polymers and carbon nanotubes.

The electroconductive layer 30 may be a film having a plurality of through holes formed therein and having a uniform thickness, or may be a woven fabric. The fiber forming the woven fabric may be an organic material such as electroconductive polymers and carbon nanotubes, or may be an inorganic material such as metals and alloys.

The opening ratio of the electroconductive layer 30 is not limited to a specific value as long as the value D is 1.3 or more in the radio wave absorber 1a. The electroconductive layer 30 has, for example, an opening ratio of 65% or more. Accordingly, the electroconductive layer 30 easily has high transparency. The opening ratio of the electroconductive layer 30 is a ratio Sas/(Sas+Sbs) of an opening area Sas of the plurality of second openings 31 to a sum Sas+Sbs of the opening area Sas of the plurality of second openings 31 and an area Sbs of the non-opening portion of the electroconductive layer 30 when the electroconductive layer 30 is viewed in a plan view.

The opening ratio of the electroconductive layer 30 is desirably 70% or more and more desirably 75% or more. The opening ratio of the electroconductive layer 30 is, for example, 99% or less, and may be 98% or less, or may be 97% or less.

The arrangement of the plurality of second openings 31 is not limited to a specific arrangement as long as the value D is 1.3 or more in the radio wave absorber 1a. For example, the second direction may include a plurality of alignment directions intersecting each other. For example, in the electroconductive layer 30, the plurality of second openings 31 are arranged such that the centers thereof form a square lattice on the second main surface 32. In other words, in the electroconductive layer 30, the second direction includes alignment directions orthogonal to each other. In the radio wave absorber 1a, the second direction is, for example, a direction extending parallel to the first direction.

The shape of each second opening 31 is not limited to a specific shape as long as the value D is 1.3 or more in the radio wave absorber 1a. For example, each second opening 31 has a square shape in a plan view.

The dielectric layer 20 has, for example, a visible light transmittance of 80% or more. Accordingly, the radio wave absorber 1a easily has high transparency. As used herein, the visible light transmittance is the average value of spectral transmittances in a wavelength range of 380 nm to 780 nm.

The dielectric layer 20 has, for example, a relative permittivity of 2.0 to 20.0. In this case, it is easy to adjust the thickness of the dielectric layer 20, and it is easy to adjust the radio wave absorption performance of the radio wave absorber 1a. The relative permittivity of the dielectric layer 20 is, for example, a relative permittivity at 10 GHz measured according to the cavity resonance method.

The dielectric layer 20 is formed, for example, from a predetermined polymer. The dielectric layer 20 contains, for example, at least one polymer selected from the group consisting of ethylene-vinyl acetate copolymer, vinyl chloride resin, urethane resin, acrylic resin, acrylic urethane resin, acrylic-based elastomer, polyethylene, polypropylene, silicone, polyethylene terephthalate, polyethylene naphthalate, polycarbonate, polyimide, and cycloolefin polymer. In this case, it is easy to adjust the thickness of the dielectric layer 20, and the production cost of the radio wave absorber 1a can be kept low. The dielectric layer 20 can be produced, for example, by hot-pressing a predetermined resin composition.

The dielectric layer 20 may be formed as a single layer, or may be formed of a plurality of layers made of the same material or different materials. In the case where the dielectric layer 20 has n layers (n is an integer equal to or greater than 2), the relative permittivity of the dielectric layer 20 is determined as follows, for example. A relative permittivity εᵢ of each layer is measured (i is an integer from 1 to n). Next, εᵢ×(tᵢ/T) is obtained by multiplying the measured relative permittivity εᵢ of each layer by the ratio of a thickness tᵢ of the layer to a total thickness T of the dielectric layer 20. The relative permittivity of the dielectric layer 20 can be determined by adding up εᵢ×(tᵢ/T) of all the layers.

As shown in FIG. 2A, the dielectric layer 20 includes, for example, a first layer 21, a second layer 22, and a third layer 23. The first layer 21 is disposed between the second layer 22 and the third layer 23. The first layer 21 contains, for example, at least one member selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer.

In the radio wave absorber 1a, the second layer 22 serves as a substrate for the resistive layer 10, for example. In this case, the resistive layer 10 can be produced, for example, by forming the plurality of first openings 11 by laser processing, etching, or the like in a non-porous film formed on one main surface of the second layer 22 by a film forming method such as sputtering. In some cases, a non-porous film for the resistive layer 10 may be formed by a film forming method such as ion plating or coating (for example, bar coating).

The second layer 22 is disposed, for example, at a position closer to the electroconductive layer 30 than the resistive layer 10 is. As shown in FIG. 2B, the second layer 22 may be disposed at a position farther from the electroconductive layer 30 than the resistive layer 10 is. In this case, the dielectric layer 20 is composed of the first layer 21 and the third layer 23. In this case, the resistive layer 10 and the dielectric layer 20 are protected by the second layer 22, and the radio wave absorber 1a has high durability. In this case, for example, the resistive layer 10 may be in contact with the first layer 21. The material of the second layer 22 is, for example, polyethylene terephthalate (PET), polyethylene naphthalate (PEN), acrylic resin (PMMA), polycarbonate (PC), polyimide (PI), or cycloolefin polymer (COP). Among them, the material of the second layer 22 is desirably PET in terms of the balance among good heat resistance, dimensional stability, and manufacturing cost.

In the radio wave absorber 1a, the third layer 23 serves as a substrate for the electroconductive layer 30, for example. In this case, the electroconductive layer 30 can be produced, for example, by forming the plurality of second openings 31 by laser processing, etching, or the like in a non-porous film formed on one main surface of the third layer 23 by a film forming method such as sputtering. In some cases, a non-porous film for the electroconductive layer 30 may be formed by a film forming method such as ion plating or coating (for example, bar coating). As shown in FIG. 2A, the third layer 23 is disposed, for example, at a position closer to the resistive layer 10 in the radio wave absorber 1a than the electroconductive layer 30 is. As shown in FIG. 2C, the third layer 23 may be disposed at a position farther from the resistive layer 10 than the electroconductive layer 30 is. In this case, for example, the electroconductive layer 30 is in contact with the first layer 21.

As the material of the third layer 23, for example, the materials exemplified as the material of the second layer 22 can be used. The material of the third layer 23 may be the same as or different from the material of the second layer 22. The material of the third layer 23 is desirably PET in terms of the balance among good heat resistance, dimensional stability, and manufacturing cost.

The third layer 23 has, for example, a thickness of 10 to 150 μm, and desirably has a thickness of 15 to 100 μm. Accordingly, the flexural rigidity of the third layer 23 is low, and it is possible to suppress wrinkling or deformation of the third layer 23 when forming the electroconductive layer 30. The third layer 23 may be omitted in some cases.

The first layer 21 may be composed of a plurality of layers. In particular, in the case where the first layer 21 is in contact with at least one of the resistive layer 10 and the electroconductive layer 30 as shown in FIG. 2B or FIG. 2C, the first layer 21 can be composed of a plurality of layers.

The first layer 21 may have adhesiveness, or may not necessarily have adhesiveness. In the case where the first layer 21 has adhesiveness, an adhesive layer may be disposed in contact with at least one of both main surfaces of the first layer 21, or adhesive layers may not necessarily be disposed in contact with both main surfaces of the first layer 21, respectively. In the case where the first layer 21 does not have adhesiveness, adhesive layers are desirably disposed in contact with both main surfaces of the first layer 21, respectively. In the case where the dielectric layer 20 includes the second layer 22, even if the second layer 22 does not have adhesiveness, adhesive layers may not necessarily be disposed in contact with both main surfaces of the second layer 22, respectively. In this case, an adhesive layer can be disposed in contact with one main surface of the second layer 22. In the case where the dielectric layer 20 includes the third layer 23, even if the third layer 23 does not have adhesiveness, adhesive layers may not necessarily be disposed in contact with both main surfaces of the third layer 23, respectively. In this case, an adhesive layer can be disposed in contact with at least one main surface of the third layer 23. Each adhesive layer contains, for example, a rubber-based adhesive agent, an acrylic-based adhesive agent, a silicone-based adhesive agent, or a urethane-based adhesive agent. The thickness of each adhesive layer containing the adhesive agent is not limited to a specific value, and is, for example, 3 to 50 μm, and desirably 5 to 30 μm.

The radio wave absorber 1a has, for example, a visible light transmittance of 50% or more.

The radio wave absorber 1a is, for example, a λ/4 radio wave absorber. The radio wave absorber 1a is designed such that, when radio waves of a wavelength λ₀ to be absorbed by the radio wave absorber 1a are incident on the radio wave absorber 1a, radio waves resulting from reflection on the front surface of the resistive layer 10 (front surface reflection) and radio waves resulting from reflection on the electroconductive layer 30 (back surface reflection) interfere with each other. In the λ/4 radio wave absorber, as shown in the following equation (1), the wavelength λ₀ of the radio waves to be absorbed is determined according to a thickness t of the dielectric layer 20 and a relative permittivity εᵣ of the dielectric layer 20. That is, the radio waves of the wavelength to be absorbed can be set by adjusting the relative permittivity and the thickness of the dielectric layer as appropriate. In the equation (1), sqrt(εᵣ) means the square root of the relative permittivity εᵣ.

λ₀=4t×sqrt(εᵣ) Equation (1)

The radio wave absorber 1a may contain at least one of a dielectric loss material and a magnetic loss material. In other words, the radio wave absorber 1a may be a dielectric loss radio wave absorber or a magnetic loss radio wave absorber. The dielectric layer 20 may contain at least one of a dielectric loss material and a magnetic loss material. The material forming the resistive layer 10 may be magnetic.

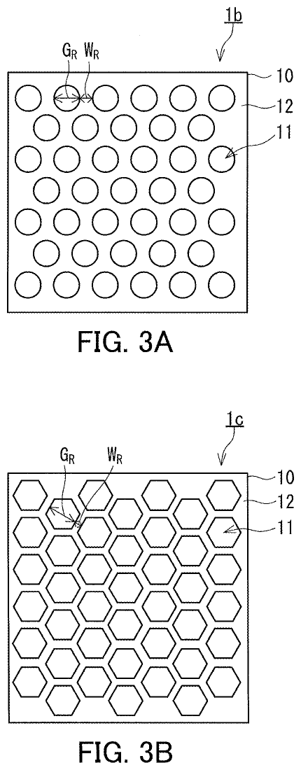

As for the arrangement and the shapes of the plurality of first openings 11, the radio wave absorber 1a may be modified into a radio wave absorber 1b shown in FIG. 3A, a radio wave absorber 1c shown in FIG. 3B, or a radio wave absorber 1d shown in FIG. 3C. Each of the radio wave absorber 1b, the radio wave absorber 1c, and the radio wave absorber 1d is configured in the same manner as the radio wave absorber 1a, except for the portions that are particularly described. The components, of the radio wave absorber 1b, the radio wave absorber 1c, and the radio wave absorber 1d, identical to or corresponding to the components of the radio wave absorber 1a are indicated by the same reference characters, and the detailed descriptions thereof are omitted. The descriptions given for the radio wave absorber 1a are also applicable to the radio wave absorber 1b, the radio wave absorber 1c, and the radio wave absorber 1d unless there is a technical inconsistency.

As shown in FIG. 3A, in the radio wave absorber 1b, the plurality of first openings 11 each have a circular shape in a plan view. In addition, the plurality of first openings 11 are arranged such that the centers thereof form a parallelogram lattice on the first main surface 12. The plurality of first openings 11 may be arranged so as to form a square lattice. The radio wave absorber 1a may be modified such that the plurality of second openings 31 each have a circular shape in a plan view and the centers thereof form a parallelogram lattice or a square lattice on the second main surface 32.

As shown in FIG. 3B, in the radio wave absorber 1c, the plurality of first openings 11 each have a regular hexagonal shape in a plan view. In addition, the plurality of openings 11 are arranged such that the centers thereof form a parallelogram lattice on the first main surface 12. The radio wave absorber 1a may be modified such that the plurality of second openings 31 each have a regular hexagonal shape in a plan view and the centers thereof form a parallelogram lattice on the second main surface 32.

As shown in FIG. 3C, in the radio wave absorber 1d, the plurality of first openings 11 each have an equilateral triangle shape in a plan view. In addition, a plurality of the first openings 11 having equilateral triangle shapes having the same orientation are arranged such that the centers thereof form a parallelogram lattice on the first main surface 12. The radio wave absorber 1a may be modified such that the plurality of second openings 31 each have an equilateral triangle shape in a plan view and the centers of a plurality of the second openings 31 having equilateral triangle shapes having the same orientation form a parallelogram lattice on the second main surface 32. Herein, the center of gravity of a planar figure is regarded as the center of an opening having a planar figure shape.

Each of the first openings 11 and the second openings 31 may have another polygonal shape such as a rectangular shape, or an elliptical shape in a plan view. Each of the plurality of first openings 11 and the plurality of second openings 31 may be arranged such that the centers thereof form another planar lattice such as a rectangular lattice on the first main surface 12 or the second main surface 32. As used herein, the planar lattice means an array of points on a plane that are unchanged as a result of parallel shift for a constant distance in each of two independent directions.

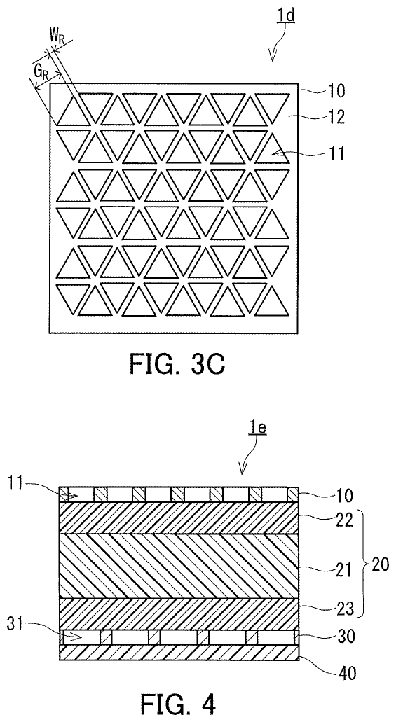

The radio wave absorber 1a may be modified into a radio wave absorber 1e shown in FIG. 4, for example. The radio wave absorber 1e is configured in the same manner as the radio wave absorber 1a except for the portions that are particularly described.

The radio wave absorber 1e further includes an adhesive layer 40. In the radio wave absorber 1b, the electroconductive layer 30 is disposed between the dielectric layer 20 and the adhesive layer 40.

For example, the radio wave absorber 1b can be adhered to a predetermined article by pressing the radio wave absorber 1b against the article with the adhesive layer 40 brought into contact with the article. Accordingly, a radio wave absorber-attached article can be obtained.

The adhesive layer 40 contains, for example, a rubber-based adhesive agent, an acrylic-based adhesive agent, a silicone-based adhesive agent, or a urethane-based adhesive agent. The radio wave absorber 1b may further include a release liner (not shown). In this case, the release liner covers the adhesive layer 40. The release liner is typically a film that can maintain the adhesive strength of the adhesive layer 40a when covering the adhesive layer 40 and that can easily be peeled from the adhesive layer 40. The release liner is, for example, a film made of polyester resin such as PET. By peeling the release liner, the adhesive layer 40 becomes exposed, allowing the radio wave absorber 1b to be adhered to an article.

### EXAMPLES

Hereinafter, the present invention will be described in more detail by means of Examples. The present invention is not limited to the following Examples. First, evaluation methods for the Examples and Comparative Examples will be described.

[D Value]

A resistive layer-attached film according to each of the Examples and the Comparative Examples was observed using an optical microscope, and the size W_{R} of the opening and the distance G_{R} between the nearest openings in the direction in which the plurality of openings were arranged at equal intervals were determined. Similarly, an electroconductive layer-attached film according to each of the Examples and the Comparative Examples was observed, and the size W_{C} of the opening and the distance G_{C} between the nearest openings in the direction in which the plurality of openings were arranged at equal intervals were determined. In each of the Examples and the Comparative Examples, a D value was determined by dividing a larger value out of the ratio G_{R}/W_{R} and the ratio G_{C}/W_{C} by a smaller value out of the ratio G_{R}/W_{R} and the ratio G_{C}/W_{C}. The results are shown in Table 1.

[Tem Observation]

Cross-sectional observation samples of a non-porous film for a resistive layer according to each of the Examples and the Comparative Examples and a non-porous film for an electroconductive layer according to each of the Examples and the Comparative Examples, the resistive layer-attached film according to each of the Examples and the Comparative Examples, and an alloy film in an electroconductive layer-attached film according to each of the Examples and the Comparative Examples were prepared using a focused ion beam processing observation apparatus (product name: FB-2000A, manufactured by Hitachi High-Tech Corporation). Then, the cross-sectional observation samples were observed using a field emission transmission electron microscope (product name: HF-2000, manufactured by Hitachi High-Tech Corporation), and the thicknesses of the non-porous film for a resistive layer according to each of the Examples and the Comparative Examples and the non-porous film for an electroconductive layer according to each of the Examples and the Comparative Examples were measured. The thicknesses of the non-porous films were regarded as the thicknesses of the resistive layer and the electroconductive layer according to each of the Examples and the Comparative Examples. The results are shown in Table 1.

[Appearance Check]

A sample according to each of the Examples and the Comparative Examples was observed with the naked eye, and whether moiré can be visually recognized was determined. When moiré was not visually recognized, the sample was evaluated as “A”, and when moiré was visually recognized, the sample was evaluated as “X”.

[Radio Wave Absorption Performance]

With reference to JIS R 1679: 2007, radio waves having frequencies of 60 to 90 GHz were made incident at an incident angle of 0° on the sample according to each of the Examples and the Comparative Examples fixed to a sample holder, using a vector network analyzer manufactured by ANRITSU CORPORATION, and a return loss |S| at each frequency was determined according to the following equation (2). In the equation (2), P₀ is the power of transmitted radio waves when radio waves are incident on a measurement target at a predetermined incident angle, and Pᵢ is the power of received radio waves in this case. Instead of the sample according to each of the Examples and the Comparative Examples, an aluminum plate was fixed to the sample holder, a return loss |S| when radio waves were incident on the plate at an incident angle of 0° was regarded as 0 dB, and the return loss |S| of each sample was determined. The plate had a face dimension of 30 cm square, and the thickness of the plate was 5 mm. For each sample, the maximum value of the return loss |S| was determined. The results are shown in Table 1.

S [dB]=10×log|Pᵢ/P₀| Equation (2)

[Visible Light Transmittance]

The visible light transmittance of each sample was measured using a spectrophotometer U-4100 manufactured by Hitachi, Ltd. The results are shown in Table 1.

[Specific Resistance and Sheet Resistance]

The sheet resistances of the resistive layer and the electroconductive layer according to each of the Examples and the Comparative Examples were measured by the eddy current method according to JIS Z 2316 using a non-contact type resistance measurement device NC-80LINE manufactured by NAPSON CORPORATION. Meanwhile, the sheet resistances of the non-porous film for a resistive layer and the non-porous film for an electroconductive layer according to each of the Examples and the Comparative Examples were measured in the same manner. The products of the thicknesses of the non-porous films measured as described above and the sheet resistances of the non-porous films measured as described above were obtained to determine the specific resistances of the materials forming the non-porous films. The specific resistance of the material forming the non-porous film for a resistive layer was regarded as the specific resistance of the material forming the resistive layer according to each of the Examples and the Comparative Examples, and the specific resistance of the material forming the non-porous film for an electroconductive layer was regarded as the specific resistance of the material forming the electroconductive layer according to each of the Examples and the Comparative Examples. The results are shown in Table 1.

### Example 1

DC magnetron sputtering was performed using an Al (aluminum) target material and an Si (silicon) target material and using argon gas as a process gas, to form an Al—Si alloy film on a PET film. In the DC magnetron sputtering, discharge involving the Al (aluminum) target material and discharge involving the Si (silicon) target material were performed simultaneously. Thus, a non-porous film for a resistive layer according to Example 1 was formed on the PET film. The specific resistance of the material forming the non-porous film for a resistive layer according to Example 1 was 5.0×10⁻⁵ Ω·cm. The non-porous film had a thickness of 35 nm. Next, using a metal laser patterning machine, a plurality of square-shaped openings were formed at equal intervals in the non-porous film for a resistive layer according to Example 1 so as to form a square lattice, to obtain a resistive layer-attached film according to Example 1. In a plan view of the resistive layer-attached film according to Example 1, the size of each opening in the direction in which the plurality of openings were arranged at equal intervals was 240 μm, and the distance between the nearest openings was 10 μm.

DC magnetron sputtering was performed using a copper (Cu) target material and using argon gas as a process gas, to form a Cu film on a PET film. Thus, a non-porous film for an electroconductive layer according to Example 1 was formed on the PET film. The specific resistance of the material forming the non-porous film for an electroconductive layer according to Example 1 was 5.0×10⁻⁶ Ω·cm. The non-porous film had a thickness of 500 nm. Next, using a metal laser patterning machine, a plurality of square-shaped openings were formed at equal intervals in the non-porous film for an electroconductive layer according to Example 1 so as to form a square lattice, to obtain an electroconductive layer-attached film according to Example 1. In a plan view of the electroconductive layer-attached film according to Example 1, the size of each opening in the direction in which the plurality of openings were arranged at equal intervals was 490 μm, and the distance between the nearest openings was 10 μm.

Next, an acrylic resin having a relative permittivity of 2.6 was molded so as to have a thickness of 480 μm, to obtain an acrylic resin layer A. The visible light transmittance of the acrylic resin layer A was 85.7%. The resistive layer-attached film according to Example 1 was put on the acrylic resin layer A such that the resistive layer of the resistive layer-attached film according to Example 1 was in contact with the acrylic resin layer A. Next, the electroconductive layer-attached film according to Example 1 was put on the acrylic resin layer A such that the electroconductive layer in the electroconductive layer-attached film was in contact with the acrylic resin layer A. Thus, a sample according to Example 1 was obtained.

### Example 2

DC magnetron sputtering was performed using a copper (Cu) target material and using argon gas as a process gas, to form a Cu film on a PET film. Thus, a non-porous film for an electroconductive layer according to Example 2 was formed on the PET film. The specific resistance of the material forming the non-porous film for an electroconductive layer according to Example 2 was 1.0×10⁻⁵ Ω·cm. The non-porous film had a thickness of 400 nm. Next, using a metal laser patterning machine, a plurality of square-shaped openings were formed at equal intervals in the non-porous film for an electroconductive layer according to Example 2 so as to form a square lattice, to obtain an electroconductive layer-attached film according to Example 2. In a plan view of the electroconductive layer-attached film according to Example 2, the size of each opening in the direction in which the plurality of openings were arranged at equal intervals was 450 μm, and the distance between the nearest openings was 50 μm.

An acrylic resin having a relative permittivity of 2.6 was molded so as to have a thickness of 540 μm, to obtain an acrylic resin layer B. A sample according to Example 2 was produced in the same manner as Example 1, except that the acrylic resin layer B was used instead of the acrylic resin layer A, and the electroconductive layer-attached film according to Example 2 was used instead of the electroconductive layer-attached film according to Example 1.

### Example 3

A non-porous film for a resistive layer according to Example 3 was formed in the same manner as Example 1, except that the conditions of the DC magnetron sputtering were adjusted such that the thickness of the non-porous film was 50 nm. Next, using a metal laser patterning machine, a plurality of square-shaped openings were formed at equal intervals in the non-porous film for a resistive layer according to Example 3 so as to form a square lattice, to obtain a resistive layer-attached film according to Example 3. In a plan view of the resistive layer-attached film according to Example 3, the size of each opening in the direction in which the plurality of openings were arranged at equal intervals was 450 μm, and the distance between the nearest openings was 50 μm.

A non-porous film for an electroconductive layer according to Example 3 was formed on a PET film in the same manner as Example 1. The specific resistance of the material forming the non-porous film for an electroconductive layer according to Example 3 was 5.0×10⁻⁶ Ω·cm. The non-porous film had a thickness of 1500 nm. Next, using a metal laser patterning machine, a plurality of square-shaped openings were formed at equal intervals in the non-porous film for an electroconductive layer according to Example 3 so as to form a square lattice, to obtain an electroconductive layer-attached film according to Example 3. In a plan view of the electroconductive layer-attached film according to Example 3, the size of each opening in the direction in which the plurality of openings were arranged at equal intervals was 490 μm, and the distance between the nearest openings was 10 μm.

Next, an acrylic resin having a relative permittivity of 2.6 was molded so as to have a thickness of 550 μm, to obtain an acrylic resin layer C. The resistive layer-attached film according to Example 3 was put on the acrylic resin layer C such that the resistive layer of the resistive layer-attached film according to Example 3 was in contact with the acrylic resin layer C. Next, the electroconductive layer-attached film according to Example 3 was put on the acrylic resin layer C such that the electroconductive layer in the electroconductive layer-attached film was in contact with the acrylic resin layer C. Thus, a sample according to Example 3 was obtained.

### Comparative Example 1

A non-porous film for a resistive layer according to Comparative Example 1 was formed on a PET film and a resistive layer-attached film according to Comparative Example 1 was obtained, in the same manner as Example 1 except for the following. In DC magnetron sputtering, the ratio of the discharge power of the discharge involving the Si (silicon) target material to the discharge power of the discharge involving the Al (aluminum) target material was adjusted such that the specific resistance of the material forming the resistive layer according to Comparative Example 1 was 1.0×10⁻⁴ Ω·cm. In addition, the conditions of the DC magnetron sputtering were adjusted such that the thickness of the alloy film in the resistive layer-attached film according to Comparative Example 1 was 30 nm. Next, using a metal laser patterning machine, a plurality of square-shaped openings were formed at equal intervals in the non-porous film for a resistive layer according to Comparative Example 1 so as to form a square lattice, to obtain a resistive layer-attached film according to Comparative Example 1. In a plan view of the resistive layer-attached film according to Comparative Example 1, the size of each opening in the direction in which the plurality of openings were arranged at equal intervals was 90 μm, and the distance between the nearest openings was 10 μm.

An electroconductive layer-attached film according to Comparative Example 1 was obtained in the same manner as Example 2, except that the thickness of the non-porous film was adjusted to 1000 nm. An acrylic resin having a relative permittivity of 2.6 was molded so as to have a thickness of 500 μm, to obtain an acrylic resin layer D.

A sample according to Comparative Example 1 was obtained in the same manner as Example 2, except that the acrylic resin layer D was used instead of the acrylic resin layer B, the resistive layer-attached film according to Comparative Example 1 was used instead of the resistive layer-attached film according to Example 1, and the electroconductive layer-attached film according to Comparative Example 1 was used instead of the electroconductive layer-attached film according to Example 2.

### Comparative Example 2

A non-porous film for a resistive layer according to Comparative Example 2 was formed in the same manner as Comparative Example 1. Using a metal laser patterning machine, a plurality of square-shaped openings were formed at equal intervals in the non-porous film for a resistive layer according to Comparative Example 2 so as to form a square lattice, to obtain a resistive layer-attached film according to Comparative Example 2. In a plan view of the resistive layer-attached film according to Comparative Example 2, the size of each opening in the direction in which the plurality of openings were arranged at equal intervals was 91.6 μm, and the distance between the nearest openings was 8.3 μm.

A non-porous film for an electroconductive layer according to Comparative Example 2 was formed in the same manner as Example 2, except that the thickness of the non-porous film was adjusted to 1000 nm. Using a metal laser patterning machine, a plurality of square-shaped openings were formed at equal intervals in the non-porous film for an electroconductive layer according to Comparative Example 2 so as to form a square lattice, to obtain an electroconductive layer-attached film according to Comparative Example 2. In a plan view of the electroconductive layer-attached film according to Comparative Example 2, the size of each opening in the direction in which the plurality of openings were arranged at equal intervals was 448.8 μm, and the distance between the nearest openings was 51.2 μm.

A sample according to Comparative Example 2 was produced in the same manner as Comparative Example 1, except that the resistive layer-attached film according to Comparative Example 2 was used instead of the resistive layer-attached film according to Comparative Example 1, and the electroconductive layer-attached film according to Comparative Example 2 was used instead of the electroconductive layer-attached film according to Comparative Example 1.

### Comparative Example 3

A non-porous film for an electroconductive layer according to Comparative Example 3 was formed in the same manner as Example 2, except that the thickness of the non-porous film was adjusted to 1000 nm. Using a metal laser patterning machine, a plurality of square-shaped openings were formed at equal intervals in the non-porous film for an electroconductive layer according to Comparative Example 3 so as to form a square lattice, to obtain an electroconductive layer-attached film according to Comparative Example 3. In a plan view of the electroconductive layer-attached film according to Comparative Example 3, the size of each opening in the direction in which the plurality of openings were arranged at equal intervals was 90 μm, and the distance between the nearest openings was 10 μm.

An acrylic resin having a relative permittivity of 2.6 was molded so as to have a thickness of 590 μm, to obtain an acrylic resin layer E. A sample according to Comparative Example 3 was produced in the same manner as Comparative Example 1, except that the acrylic resin layer E was used instead of the acrylic resin layer D, and the electroconductive layer-attached film according to Comparative Example 3 was used instead of the electroconductive layer-attached film according to Comparative Example 1.

As shown in Table 1, the sample according to each Example had a high visible light transmittance and had good radio wave absorption performance. In addition, moiré was not visually recognized in the sample according to each Example. On the other hand, moiré was visually recognized in the sample according to each Comparative Example. The comparison between the Examples and the Comparative Examples suggests that the D value being 1.3 or more is advantageous in making it less likely to visually recognize moiré.

TABLE 1

| | Resistive layer | | | | | |
|---|---|---|---|---|---|---|
| | Distance W_{R} | | | | Specific | |
| | between | Size G_{R} of | | | resistance | Sheet |
| | openings | opening | | Thickness | of material | resistance |
| | [μm] | [μm] | G_{R}/W_{R} | [nm] | [Ωcm] | [Ω/□] |
| Ex. 1 | 10 | 240 | 24 | 35 | 5.0 × 10⁻⁵ | 357 |
| Ex. 2 | 10 | 240 | 24 | 35 | 5.0 × 10⁻⁵ | 357 |
| Ex. 3 | 50 | 450 | 9 | 50 | 5.0 × 10⁻⁵ | 100 |
| Comp. Ex. 1 | 10 | 90 | 9 | 30 | 1.0 × 10⁻⁴ | 333 |
| Comp. Ex. 2 | 8.3 | 91.6 | 10.9 | 30 | 1.0 × 10⁻⁴ | 387 |
| Comp. Ex. 3 | 10 | 90 | 9 | 30 | 1.0 × 10⁻⁴ | 333 |
| | Electroconductive layer | | | | | |
| | Distance W_{C} | | | | Specific | |
| | between | Size G_{C} of | | | resistance | Sheet |
| | openings | opening | | Thickness | of material | resistance |
| | [μm] | [μm] | G_{C}/W_{C} | [nm] | [Ω · cm] | [Ω/□] |
| Ex. 1 | 10 | 490 | 49 | 500 | 5.0 × 10⁻⁶ | 5.0 |
| Ex. 2 | 50 | 450 | 9 | 400 | 1.0 × 10⁻⁵ | 2.5 |
| Ex. 3 | 10 | 490 | 49 | 1500 | 5.0 × 10⁻⁶ | 1.67 |
| Comp. Ex. 1 | 50 | 450 | 9 | 1000 | 1.0 × 10⁻⁵ | 0.50 |
| Comp. Ex. 2 | 51.2 | 448.8 | 8.8 | 1000 | 1.0 × 10⁻⁵ | 0.49 |
| Comp. Ex. 3 | 10 | 90 | 9 | 1000 | 1.0 × 10⁻⁵ | 0.50 |

| | Dielectric | | | | |
|---|---|---|---|---|---|
| | layer | | | Visual | |
| | Thickness | | Return loss | recognition | Visible light |
| | [μm] | D value | [dB] | of moiré | transmittance |
| Ex. 1 | 480 | 2.04 | 16.7 | A | 70.8 |
| Ex. 2 | 540 | 2.67 | 22.0 | A | 59.7 |
| Ex. 3 | 550 | 5.44 | 18.2 | A | 62.2 |
| Comp. Ex. 1 | 500 | 1.00 | 17.1 | X | 52.5 |
| Comp. Ex. 2 | 500 | 1.24 | 25.6 | X | 53.4 |
| Comp. Ex. 3 | 590 | 1.00 | 20.7 | X | 52.5 |

1. A radio wave absorber comprising:
a resistive layer having a first main surface and having a plurality of first openings formed at equal intervals in a first direction along the first main surface;
an electroconductive layer having a second main surface and having a plurality of second openings formed at equal intervals in a second direction along the second main surface; and
a dielectric layer disposed between the resistive layer and the electroconductive layer in a thickness direction of the resistive layer, wherein
a value obtained by dividing a larger value out of a first ratio and a second ratio by a smaller value out of the first ratio and the second ratio is 1.3 or more, the first ratio being a ratio of a size of the first opening in the first direction to a distance between the nearest first openings, and the second ratio being a ratio of a size of the second opening in the second direction to a distance between the nearest second openings.

2. The radio wave absorber according to claim 1, wherein the distance between the first openings is 10 μm or less.

3. The radio wave absorber according to claim 1, wherein the distance between the second openings is 10 μm or less.

4. The radio wave absorber according to claim 1, wherein the resistive layer has an opening ratio of 65% or more.

5. The radio wave absorber according to claim 1, wherein the electroconductive layer has an opening ratio of 65% or more.

6. The radio wave absorber according to claim 1, wherein the dielectric layer has a visible light transmittance of 80% or more.

7. The radio wave absorber according to claim 1, wherein the radio wave absorber has a visible light transmittance of 50% or more.
